(19) United States
(12) Patent Application Publication
(10) Pub. No.: US 2024/0128192 A1
(43) Pub. Date: Apr. 18, 2024

(54) BACKSIDE POWER WITH ON-DIE POWER SWITCHES

(71) Applicant: Advanced Micro Devices, Inc., Santa Clara, CA (US)

(72) Inventors: Suphachai Sutanthavibul, Austin, TX (US); Richard T. Schultz, Fort Collins, CO (US)

(21) Appl. No.: 18/047,482

(22) Filed: Oct. 18, 2022

(51) Int. Cl. H01L 23/528; H01L 21/768; H01L 23/48; H01L 23/525

(52) U.S. Cl. CPC H01L 23/5286; H01L 21/76895; H01L 21/76898; H01L 23/481; H01L 23/525

(57) ABSTRACT

An apparatus and method for efficiently routing power signals across a semiconductor die. In various implementations, an integrated circuit includes a micro through silicon via (TSV) that traverses a silicon substrate layer to a backside metal layer. The integrated circuit also includes power switches. The integrated circuit routes a power supply signal from the output of a power switch to a frontside power rail using the micro TSV and the backside metal layer. The integrated circuit also routes the power supply signal from the output of the power switch to the frontside power rail using a frontside metal layer. Therefore, the frontside metal layer and the backside metal layer provide power connection redundancy that increases charge sharing, improves wafer yield, reduces voltage droop, and reduces on-die area. In addition, the process routes a ground reference voltage level using both a frontside power rail and a backside power rail.

### BACKGROUND

### Description of the Relevant Art

As both semiconductor manufacturing processes advance and on-die geometric dimensions reduce, semiconductor chips provide more functionality and performance. While many advances have been made, design issues still arise with modern techniques in processing and integrated circuit design that limit potential benefits. For example, voltage droop of modern integrated circuits has become an increasing design issue with each generation of semiconductor chips. Voltage droop is a reduction in voltage value, or a AV, on a node that causes the voltage value to fall below a minimum threshold. For memories and latches without recovery circuitry, stored values can be lost. Voltage droop constraints are not only an issue for portable computers and mobile communication devices, but also for high-performance desktop computers and server computers that use superscalar microprocessors. There is dynamic voltage droop on the semiconductor chip that is caused by circuit capacitive and inductive elements. Circuit techniques, such as signal shielding and reducing the lengths of buses between repeaters, are used to reduce this type of voltage droop on the semiconductor chips.

Additionally, there is a resistive voltage droop, which is also referred to as the “IR droop,” that is proportional to the multiplicative product of the current (I) flowing through a metal trace and the resistance (R) of this metal trace. Some of these metal traces are between the motherboard and a node of a transistor. Typically, the semiconductor chip includes 12 or more metal layers between the motherboard and nodes of transistors. The voltage droop, such as the IR droop, increases as the number of metal layers increase. In addition to control signals and data signals, power supply voltage references are also routed through these 12 or more metal layers. As the number of nodes and signals increase on the semiconductor chip to provide more functionality, the area for routing the power signals, such as the power supply voltage references and the ground voltage references, reduce. Therefore, these power signals are routed again through numerous metal layers, which further increases the IR droop.

Further, traversing the multiple metal layers to route the power signals across the semiconductor chip increases the distance between contacts to the power signals. This distance widens the floorplan. The floorplan of the semiconductor die is limited unless the semiconductor package size increases. If the area for components of the die is not present in the floorplan, then the components do not fit on the same die. Accordingly, significant redesign is required along with possible moving or shifting of macro blocks in the floorplan. Such redesign consumes an appreciable amount of design time, which delays product releases.

In view of the above, methods and systems for efficiently routing power signals across semiconductor dies are desired.

### BRIEF DESCRIPTION OF THE DRAWINGS

FIG. 1 is a generalized diagram of a top view of a standard cell layout that utilizes techniques to reduce voltage droop and reduce on-die area.

FIG. 2 is a generalized block diagram of a cross-section view of power connections that utilizes techniques to reduce voltage droop and reduce on-die area.

FIG. 3 is a generalized block diagram of a cross-section view of power connections that utilizes techniques to reduce voltage droop and reduce on-die area.

FIG. 4 is a generalized block diagram of a cross-section view of power connections that utilizes techniques to reduce voltage droop and reduce on-die area.

FIG. 5 is a generalized block diagram of a cross-section view of power connections that utilizes techniques to reduce voltage droop and reduce on-die area.

FIG. 6 is a generalized block diagram of a top view of a standard cell layout that utilizes techniques to reduce voltage droop and reduce on-ide area.

FIG. 7 is a generalized block diagram is shown of a cross-section view of power connections 700 that uses the stack of metal layers.

FIG. 8 is a generalized block diagram of a method for efficiently creating integrated circuit layout for standard cells that utilizes techniques to reduce voltage droop and reduce on-die area.

FIG. 9 is a generalized block diagram of a top view of a standard cell layout that utilizes techniques to reduce voltage droop and reduce on-ide area.

FIG. 10 is a generalized block diagram is shown of a computing system 1000 with standard cells that utilizes techniques to reduce voltage droop and reduce on-die area.

FIG. 11 is a generalized block diagram of a top view of a standard cell layout that utilizes techniques to reduce voltage droop and reduce on-ide area.

FIG. 12 is a generalized block diagram of a top view of a standard cell layout that utilizes techniques to reduce voltage droop and reduce on-ide area.

FIG. 13 is a generalized block diagram of a top view of a standard cell layout that utilizes techniques to reduce voltage droop and reduce on-ide area.

FIG. 14 is a generalized block diagram of a top view of a standard cell layout that utilizes techniques to reduce voltage droop and reduce on-ide area.

While the invention is susceptible to various modifications and alternative forms, specific implementations are shown by way of example in the drawings and are herein described in detail. It should be understood, however, that drawings and detailed description thereto are not intended to limit the invention to the particular form disclosed, but on the contrary, the invention is to cover all modifications, equivalents and alternatives falling within the scope of the present invention as defined by the appended claims.

### DETAILED DESCRIPTION

In the following description, numerous specific details are set forth to provide a thorough understanding of the present invention. However, one having ordinary skill in the art should recognize that the invention might be practiced without these specific details. In some instances, well-known circuits, structures, and techniques have not been shown in detail to avoid obscuring the present invention. Further, it will be appreciated that for simplicity and clarity of illustration, elements shown in the figures have not necessarily been drawn to scale. For example, the dimensions of some of the elements are exaggerated relative to other elements.

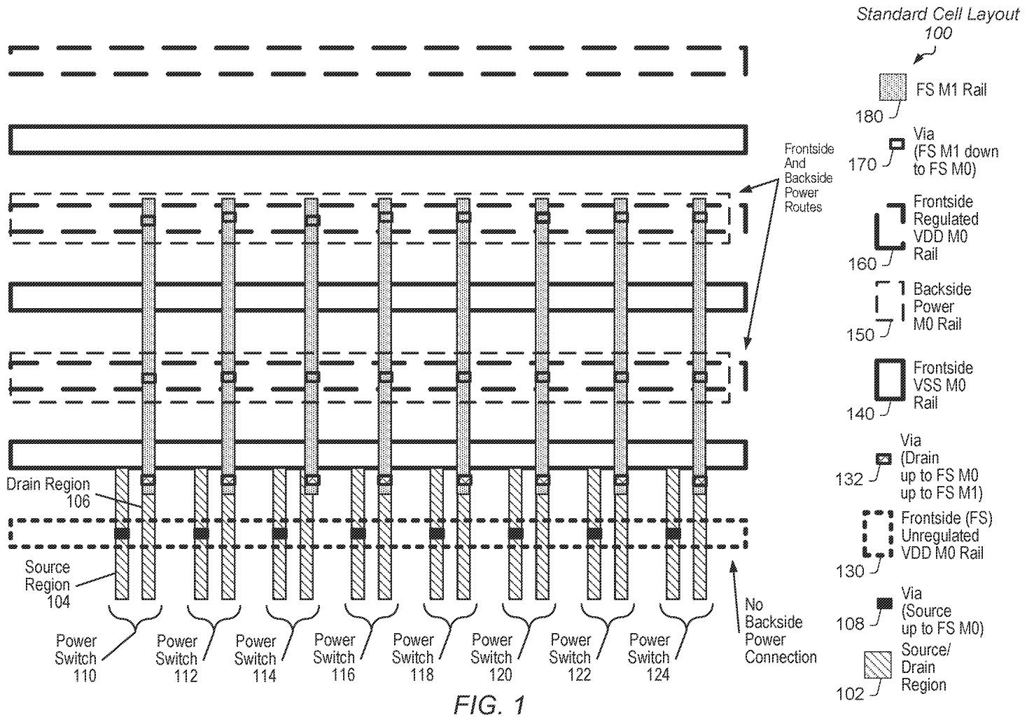

Apparatuses and methods efficiently routing power signals across a semiconductor die are contemplated. In various implementations, an integrated circuit includes a micro through silicon via (TSV) that traverses a silicon substrate layer to a backside metal layer. The integrated circuit also includes power switches on the semiconductor die. The integrated circuit routes a power supply signal from the output of a power switch to a frontside power rail using the micro TSV and the backside metal layer. The integrated circuit also routes the power supply signal from the output of the power switch to the frontside power rail using a frontside metal layer. Therefore, the frontside metal layer and the backside metal layer provide power connection redundancy that increases charge sharing, improves wafer yield, reduces voltage droop, and reduces on-die area. In addition, the process routes a ground reference voltage level using both a frontside power rail and a backside power rail. Further details of the integrated circuit are provided in the following description of FIGS. 1-10.

Referring to FIG. 1, a generalized block diagram is shown of a top view of a standard cell layout 100 that utilizes techniques to reduce voltage droop and reduce on-die area. In the illustrated implementation, the standard cell layout 100 is for any of a variety of types of Boolean gates and complex gates that include transistors arranged in a particular manner for providing data processing functionality or providing data storage. As used herein, a “transistor” is also referred to as a “semiconductor device” or a “device.” For ease of illustration, multiple layers are not shown, which are used to complete the circuitry the layout 100. For example, at least active regions and upper metal layers (metal one to metal twelve or higher) and corresponding contacts are not shown. The metal 0 (M0 or Metal0) layer is a frontside metal layer of multiple frontside metal layers that is closest to the transistors on the surface of the silicon substrate. In some implementations, the active regions for the p-type metal oxide semiconductor (PMOS) field effect transistors FETS (or pfets) are located near the frontside unregulated VDD M0 rail 130 and the frontside regulated VDD M0 rail 160. The silicon substrate in the active regions for the p-type devices are doped with Boron or Gallium during a semiconductor fabrication process. The active regions for the n-type metal oxide semiconductor (NMOS) FETS (or nfets) are located near the frontside VSS M0 rail 140. The silicon substrate in the active regions for the p-type devices are doped with Phosphorous or Arsenic during the semiconductor fabrication process.

Although the orientation of the standard cell layout 100 (or layout 100) is shown to have each of the frontside unregulated VDD M0 rail 130, the frontside regulated VDD M0 rail 160, and the frontside VSS M0 rail 140 routed in the horizontal direction, other orientations are possible and contemplated. It is understood that a silicon wafer, an integrated circuit, and a semiconductor package using the silicon substrate layer can be rotated and flipped. Therefore, the materials and layers being described would be rotated and flipped, and the orientations and directions would have a different meaning. Therefore, the terms “top,” “bottom,” “horizontal,” “vertical,” “above,” and “below” can change as the layout 100 is rotated or flipped, and the use of these terms in the below description correspond to the orientation being shown in the layout 100.

In some implementations, the devices (or transistors) in the standard cell layout 100 are planar devices. In other implementations, the devices (or transistors) in the standard cell layout 100 are non-planar devices. Non-planar transistors are used in semiconductor processing for reducing short channel effects. Tri-gate transistors, Fin field effect transistors (FETs), and gate all around (GAA) transistors are examples of non-planar transistors. In some implementations, the devices in the standard cell layout 100 are fabricated by one of the immersion lithography techniques, the double patterning technique, the extreme ultraviolet lithography (EUV) technique, and the directed self-assembly (DSA) lithography technique. These techniques provide the resolution of each of the width and the pitch of the layout such as at least the horizontal frontside VDD M0 rail 130 and the horizontal frontside VSS M0 rail 140. When selecting between immersion lithography, double patterning, EUV and DSA techniques, and other techniques, cost is considered as the cost increases from immersion lithography to EUV. However, over time, the costs of these techniques adjust as well as additional and newer techniques are developed for providing relatively high resolution. Accordingly, one of a variety of lithography techniques is used to provide relatively high resolution for the width and the pitch.

As used herein, a “terminal” of a transistor is also referred to as a “region” of a transistor. For example, a source region is also referred to as a source terminal, a drain region is also referred to as a drain terminal, and a gate region is also referred to as a gate terminal. In the illustrated implementation, the standard cell layout 100 uses the source and drain regions 102 in the vertical direction. Examples of the source and drain regions 102 are trench silicide contacts. In some implementations, the source and drain regions 102 include Cobalt silicide (CoSi₂). In other implementations, the source and drain regions 102 include Titanium silicide (TiSi₂).

The layout 100 uses multiple power switches 110-124. In an implementation, each of the power switches 110-124 is implemented by a p-type device with a power enable control signal routed to a gate terminal. The metal gates (not shown) of the power switches are routed in the vertical direction. Similarly, the source terminal (region) 104 and the drain terminal (region) 106 of the power switches 110-124 are also routed in the vertical direction. The source terminal 104 receives the frontside unregulated VDD M0 rail 130 through the via 108. The drain terminal 106 sends a gated (regulated) power supply reference voltage level to one or more of the frontside regulated VDD M0 rails 160. To do so, the drain terminal 106 is connected to the frontside metal 1 (M1 or Metal1) rail 180 through the M0 layer (such as a stub) and the via 132. It is noted that the via 132 would not be visible from a top view of layout 100 due to being covered by the M1 rail 180, the via 170, and the M0 layer (such as a stub). However, the via 132 is shown here to indicate the locations of the connections from the drain terminal 106 to the M0 layer (such as a stub) to the frontside M1 rail 180.

To route the regulated (power gated) power supply reference voltage level to one or more of the frontside regulated VDD M0 rails 160, the via 170 is used. Similar to the via 132, the via 170 would not be visible from a top view of layout 100 due to being covered by the M1 rail 180. The difference between the via 132 and the via 170 is that below the via 170 is located a micro through silicon via (TSV) that traverses the silicon substrate layer to reach the backside power M0 rails 150. The backside power M0 rails 150 are below the silicon substrate layer. Therefore, in the layout 100, the backside power M0 rails 150 are used for routing power connections in addition to the frontside regulated VDD M0 rails 160. Similar to the vias 132 and 170, the backside power M0 rail 150 would not be typically shown from a top view of standard cell layout since the silicon substrate layer and other elements cover backside signal routes. However, the backside power M0 rail 150 is shown here to further illustrate the use of power connection redundancy that increases charge sharing, reduces voltage droop, and reduces on-die area. For example, the backside power M0 rails 150 routed below the frontside regulated VDD M0 rails 160 provide an additional conductive routing layer. To transport current from an off-chip power supply to p-type devices, the current flows from the off-chip power supply to the frontside unregulated VDD M0 rail 130 to the power switches 110-124 to the frontside M1 rails 180, and then to each of the frontside regulated VDD M0 rails 160 and the backside power M0 rails 150.

If the voltage droop is reduced to a value below a threshold value, then performance increases and data corruption is avoided. Further, without adding extra routing in frontside metal layers, the use of the backside power M0 rail 150 scales along with standard cells as the on-die geometric dimensions reduce and the number of nodes and signals increase. In various implementations, one or more of the width and the thickness of the backside power M0 rail 150 is greater than the width and the thickness of the frontside regulated VDD M0 rails 160. These greater dimensions of the backside power M0 rail 150 further increase charge sharing and further reduce the voltage droop.

By increasing the charge sharing and reducing the voltage droop, the frontside M1 rails 180 can be used to route the power supply reference voltage level, rather than a higher metal layer that uses wider and possibly thicker metal layer dimensions than the frontside M1 rails 180. Despite the frontside M1 rails 180 having greater resistivity, the redundancy of the routing provided by the backside power M0 rail 150 still reduces the overall voltage droop. The micro TSVs (not shown) used to access the backside power M0 rail 150 are unable to be placed by the power switches 110-124. The combined area of the micro TSV and the drain region 106 could cause an electrical short connection with the frontside VSS M0 rail 140. Therefore, the frontside M1 rails 180 are used for routing. In other implementations, frontside metal 3 (M3 or Metal3) rails (not shown) are used to connect the frontside unregulated VDD M0 rail 130 to one or more of the frontside regulated VDD M0 rails 160. In addition, in some implementations, backside metal 1 (M1 or Metal1) rails (not shown) are used to connect frontside regulated VDD M0 rails 160. In such implementations, no further routing is provided by frontside vertical rails, which provides on-die area for other signal routes.

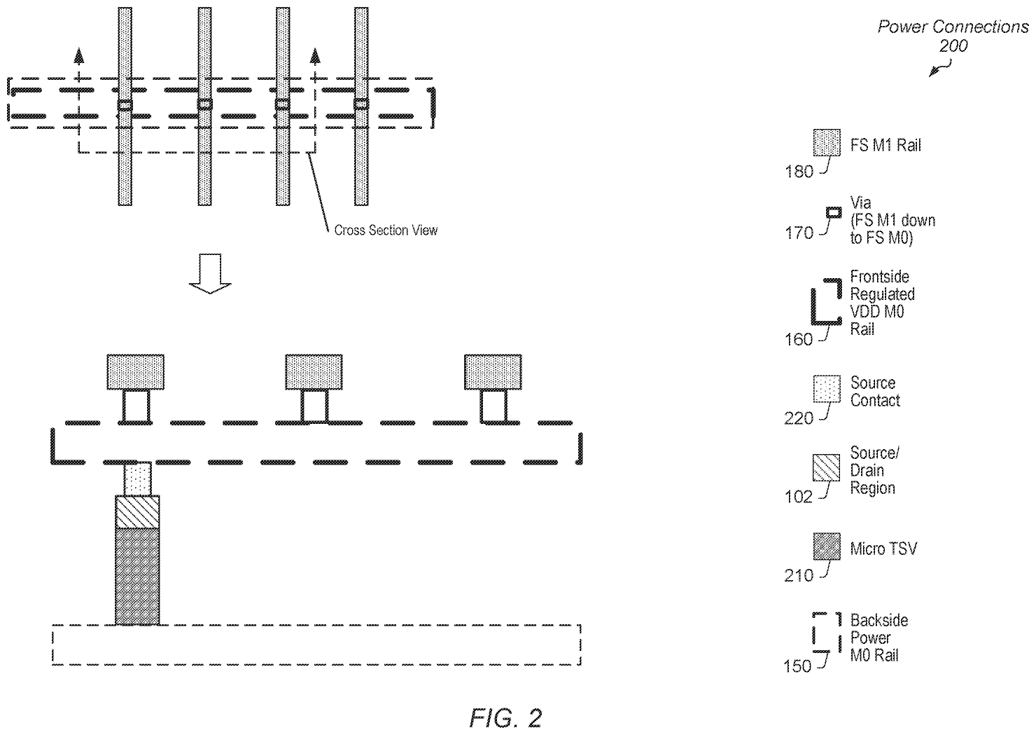

Referring now to FIG. 2, a generalized block diagram is shown of a cross-section view of power connections 200 that utilizes techniques to reduce voltage droop and reduce on-die area. Contacts (or vias), materials, structures and other layout elements described earlier are numbered identically. A top view of standard cell layout is provided at the top of FIG. 2. This top view is a portion of the layout 100 shown earlier in FIG. 1. A cross-section view of this layout is shown at the bottom of FIG. 2. The backside power M0 rail 150 is located below the silicon substrate layer and any oxide layer, which is used for isolation. In the illustrated implementation, the backside power M0 rail 150 routes a power supply reference voltage level that is also routed by the frontside regulated VDD M0 rail 160. It is noted that the below description is for routing the power supply reference voltage level (VDD) to one or two source regions 102 of p-type devices. However, the materials, components and connections can be used to also route the ground reference voltage level (VSS) to one or two source regions 102 of n-type devices.

The backside power M0 rail 150 is electrically connected to the frontside regulated VDD M0 rail 160 through the micro TSV 210 and the source contact 220. It is noted that the source contact 220 has the same functionality as the via 132 (of FIG. 1), and from a top view of the power connections 200, the source contact 220 is not visible due to being covered by the frontside M1 rail 180, the via 170, and the frontside regulated VDD M0 rail 160. In various implementations, the frontside regulated VDD M0 rail 160 is a frontside metal layer of multiple frontside metal layers that is closest to the transistors on the surface of the silicon substrate layer. The frontside M1 rails 180 are connected to the frontside regulated VDD M0 rail 160 through the vias 170. The frontside M1 rails 180 are routed into and out of the page. The frontside regulated VDD M0 rail 160 and the backside power M0 rail 150 provide power connection redundancy that increases charge sharing, improves wafer yield, reduces on-die area, and reduces voltage droop for the routing of the power supply reference voltage level (VDD).

The micro TSV 210 is formed after patterning with lithography, the silicon substrate layer is etched, and one of Cobalt (Co), Ruthenium (Ru), or other material is deposited. Following, the Cobalt silicide (Co Si₂) is patterned and formed (etched and filled) to form the source regions 102. The source regions 102 have a sidewall connection with the micro TSV 210. Next, the CMP steps planarizes together the source regions 102 and the micro TSV 210. The CMP step also polishes the remaining materials of the micro TSV 110 and the source regions 102. The CMP step achieves a near-perfect flat and smooth surface upon which further layers of integrated circuitry are built.

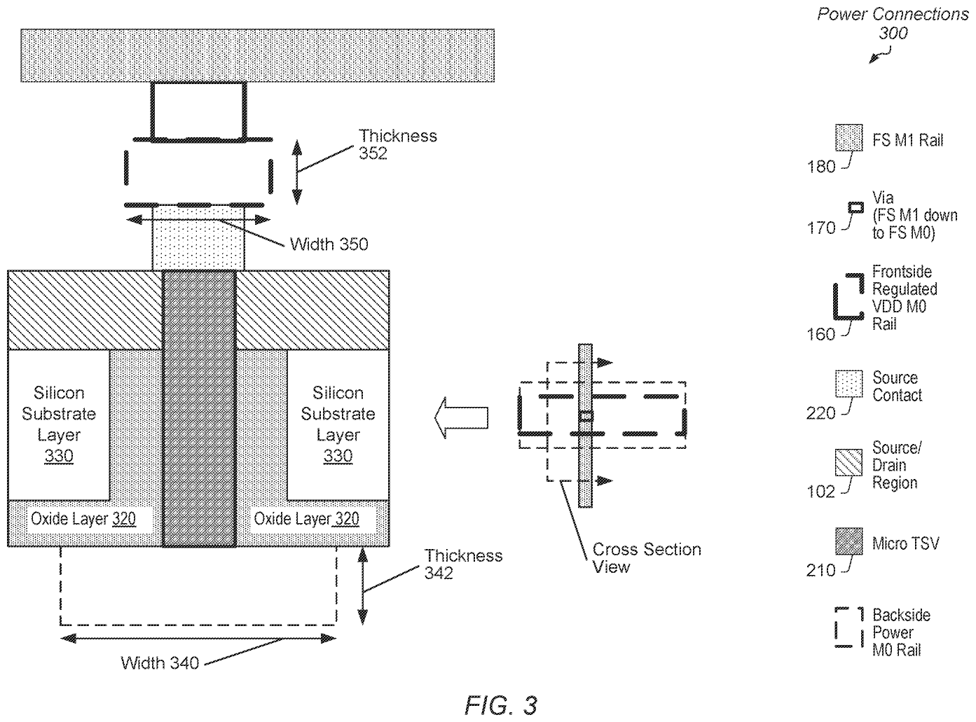

Turning now to FIG. 3, a generalized block diagram is shown of a cross-section view of power connections 300 that utilizes techniques to reduce voltage droop and reduce on-die area. Contacts (or vias), materials, structures and other layout elements described earlier are numbered identically. A top view of standard cell layout is provided at right of FIG. 3. This top view is a portion of the layout 100 shown earlier in FIG. 1. A cross-section view of this layout is shown at the left of FIG. 3. It is noted that the below description is for routing the power supply reference voltage level (VDD) to one or two source regions 102 of p-type devices. However, similar to the power connections 200 (of FIG. 2), the materials, components and connections can be used to also route the ground reference voltage level (VSS) to one or two source regions 102 of n-type devices.

The backside power M0 rail 150 is located below the silicon substrate layer 330 and the oxide layer 320, which is used for isolation. The backside power M0 rail 150 is electrically connected to the frontside regulated VDD M0 rail 160 through the micro TSV 210. As shown, the dimensions of the backside power M0 rail 150 include a width 340 and a thickness 342, and the dimensions of the frontside regulated VDD M0 rail 160 include a width 350 and a thickness 352. In some implementations, one or more of the width 340 and the thickness 342 of the backside power M0 rail 150 is greater than a respective one of the width 350 and the thickness 352 of the frontside regulated VDD M0 rail 160. Therefore, the backside power M0 rail 150 provides a less resistive path than the frontside regulated VDD M0 rail 160 to transport current from a power supply to p-type devices that include the two source regions 102 abutted with the micro TSV 210.

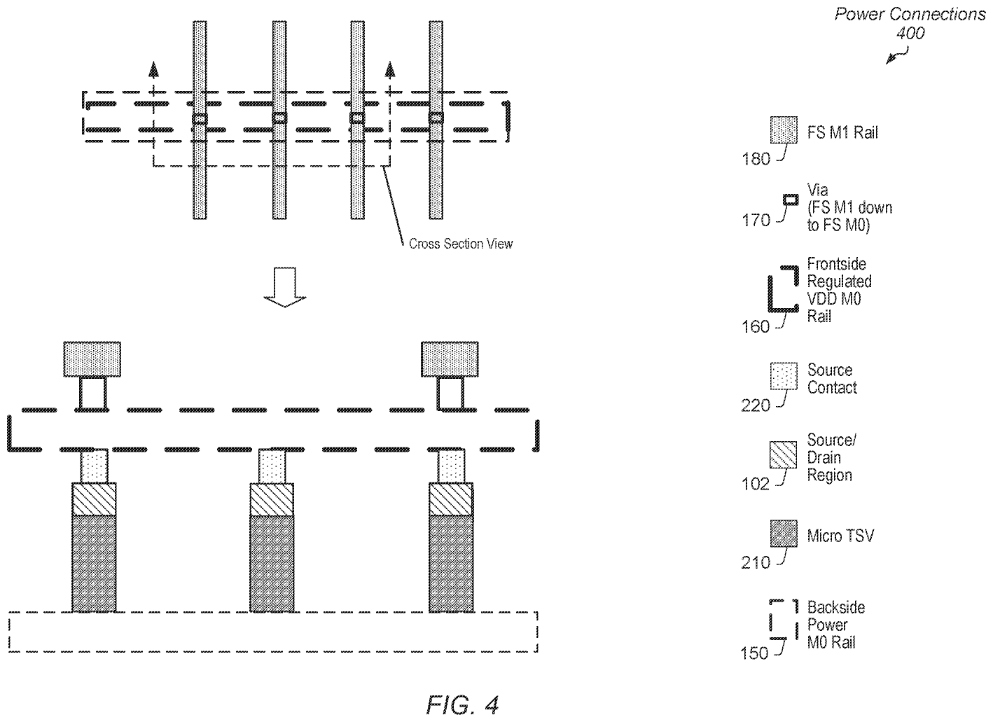

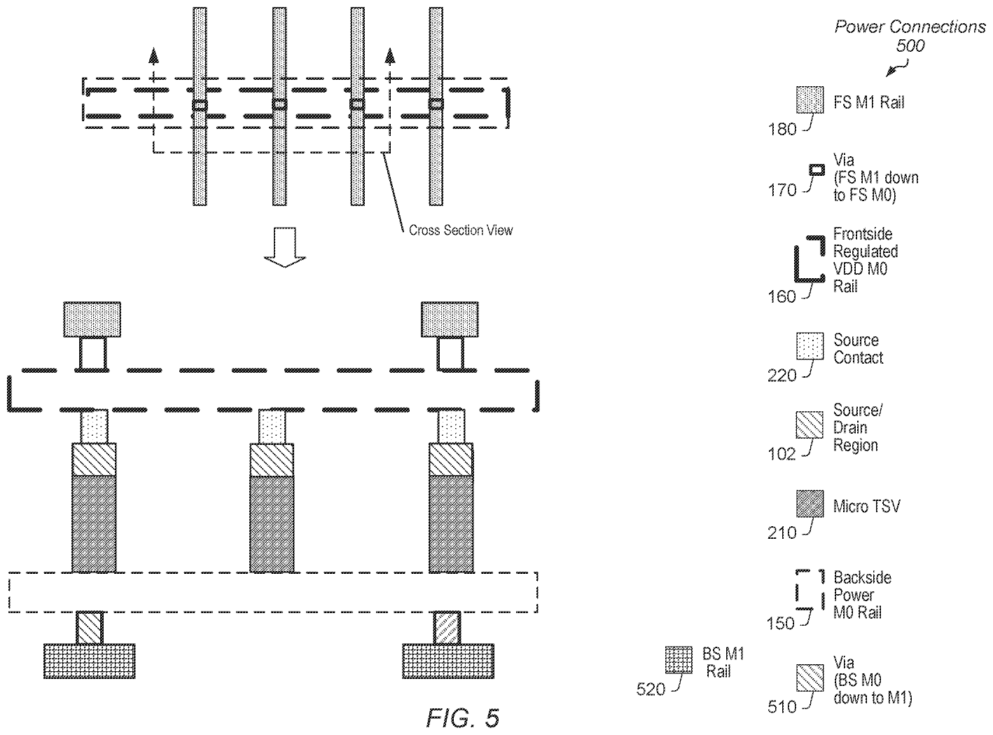

Turning now to FIG. 4, a generalized block diagram of a cross-section view of power connections 400 is shown that utilizes techniques to reduce voltage droop and reduce on-die area. Contacts (or vias), materials, structures and other layout elements described earlier are numbered identically. A top view of standard cell layout is provided at the top of FIG. 4. This top view is a portion of the layout 100 shown earlier in FIG. 1. A cross-section view of this layout is shown at the bottom of FIG. 4. The power connections 400 include multiple micro TSVs 210 between the backside power M0 rail 150 and the frontside regulated VDD M0 rail 160. The additional micro TSVs 210 increases charge sharing, improves wafer yield, and reduces voltage droop for the routing of the power supply reference voltage level (VDD). Referring to FIG. 5, a generalized block diagram of a cross-section view of power connections 500 is shown that utilizes techniques to reduce voltage droop and reduce on-die area. Power connections 500 include the same contacts (or vias), materials, structures, and other layout elements as power connections 400. However, the power connections 500 additionally includes the vias 510 and the backside (BS) power M1 rails 520 that provide further power connection redundancy that increases charge sharing, improves wafer yield, reduces on-die area, and reduces voltage droop for the routing of the power supply reference voltage level (VDD).

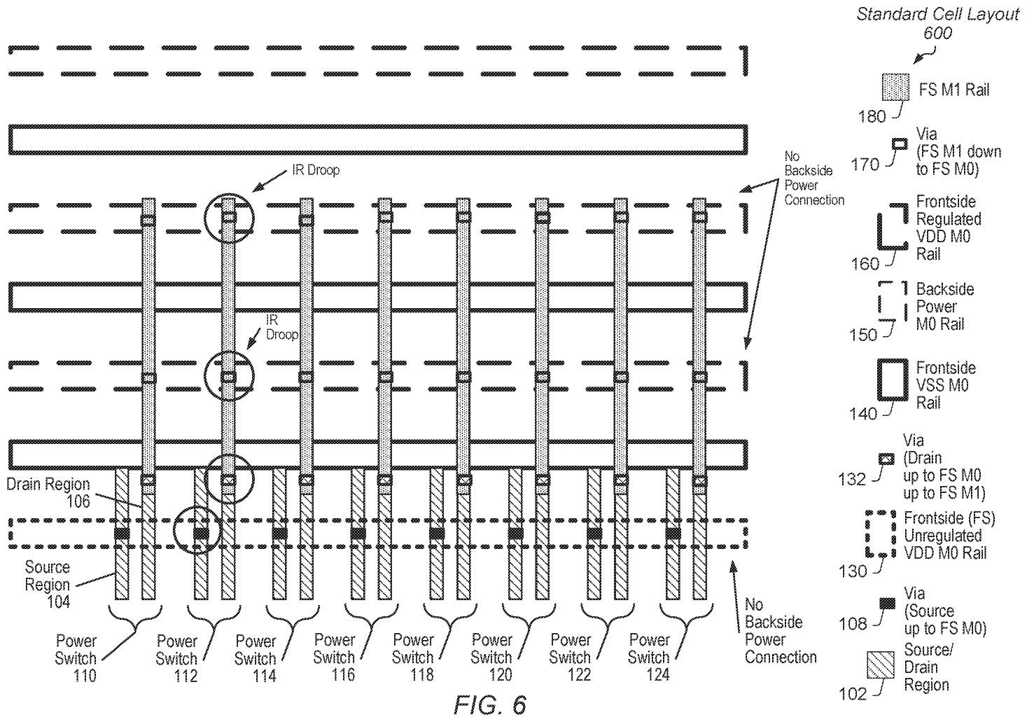

Turning now to FIG. 6, a generalized block diagram is shown of a top view of a standard cell layout 600 that utilizes techniques to reduce voltage droop and reduce on-ide area. The standard cell layout 600 includes the same contacts (or vias), materials, structures, and other layout elements as standard cell layout 100 (of FIG. 1). However, here, areas are notated by circles where multiple metal layers are used to provide a power supply reference voltage level to the frontside regulated VDD M0 rails 160 if the backside power M0 rails 150 were not used. These stacks of the multiple metal layers, such as from Metal0 (M0) to Metal 15 (M15), consume an appreciable amount of area, which determines a minimum distance between vias that connect the frontside M1 rails 180 to frontside unregulated VDD M0 rail 130 and the frontside regulated VDD M0 rail 160. Using the backside power M0 rails 150 removes the use of these stacks in each location except for the connection to the frontside unregulated VDD M0 rail 130, which is at the input of the power switches 110-124. Each of these stacks include an appreciable amount of voltage droop in addition to consuming area among the metal layers used for signal routing. It is noted again that the vias 132 and 170 and the backside power M0 rail 150 would not be visible from a top view of layout 600 due to being covered by one or more of the M1 rail 180, other vias, the silicon substrate layer, the M0 layer (such as a stub or a signal route), and so forth. However, these components are shown here to illustrate particular power connections.

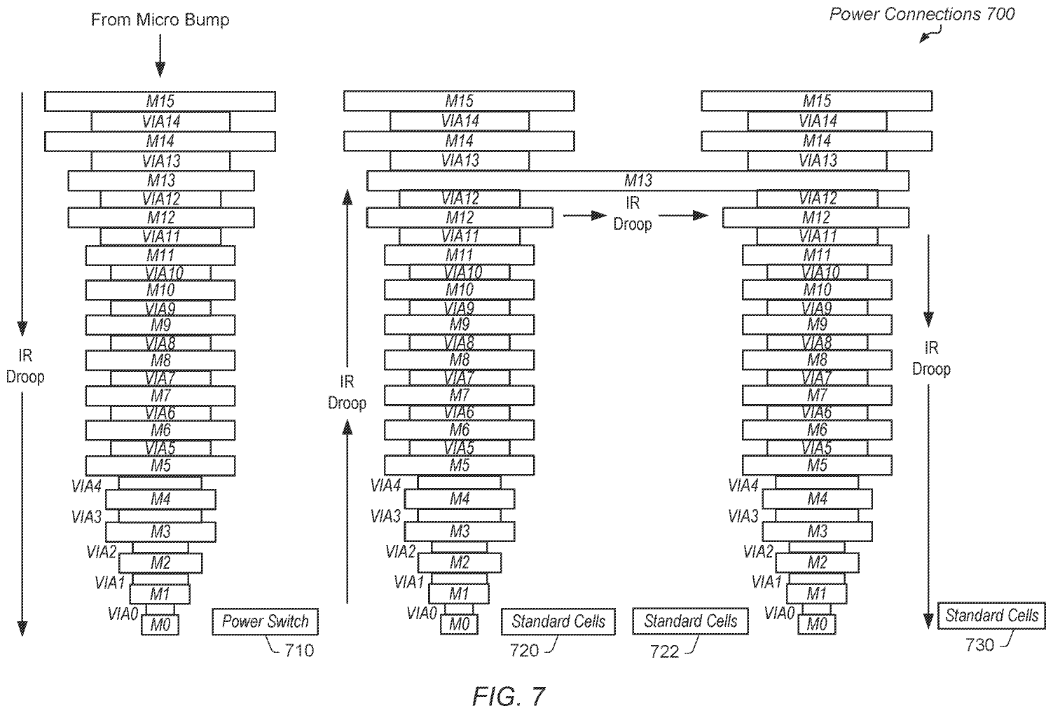

Referring to FIG. 7, a generalized block diagram is shown of a cross-section view of power connections 700 that uses the stack of metal layers. The metal layers are shown as the blocks with “M” followed by a layer number. The corresponding vias are shown between the metal layers. In the illustrated implementation, the stack of metal layers includes 16 metal layers from Metal0 (M0) to Metal15 (M15). The M15 layer receives a power supply reference voltage level from an off-chip source. For example, a micro bump used to connect the semiconductor die to an interposer or silicon substrate core provides the off-chip power supply reference voltage level. This voltage level is sent from the M15 layer down to the M0 layer. As shown, the widths and sometimes the thicknesses of the metal layers reduce for the lower metal layers. Therefore, the resistivity of these metal layers increase. The stack of metal layers (M0 layer to M15 layer) has a corresponding IR droop. Each of the metal layers and the vias in the stack provides a corresponding resistance that is combined in a serial manner with the other resistances.

The power switches 710 receive the voltage level from the stack of metal layers. The output of the power switches 710 can provide the regulated (power gated) version of the voltage level to nearby 720 and 722. When backside metal rails are not used, additional stacks are needed to route the voltage level to other nodes on the semiconductor die. The layout 600 (of FIG. 6) notated with circles some of the locations for these stacks. To route the voltage level to the standard cells 730, another stack of metal layers is used to send the voltage level on a particular metal layer such as the Metal13 (M13) layers. The M13 layer provides a signal route with the same orientation as the M1 layer described and shown earlier. Another stack of metal layers is used to route the voltage level from the M13 layer to the frontside M0 layer. The use of these stacks increases the voltage droop and consumes area of the metal layers used for signal routes. The locations to place vias on the frontside M0 layers are set by the size of these stacks, which can increase the distances to these locations. Thus, the on-die area increases. The use of the backside metal routes reduces these effects.

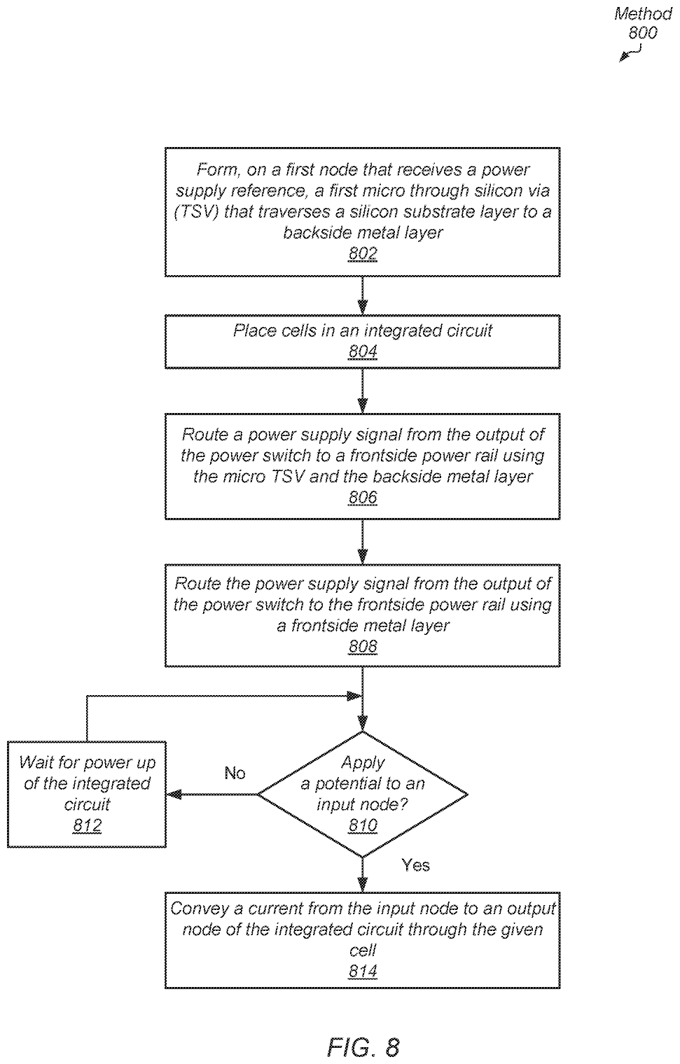

Referring now to FIG. 8, a generalized block diagram is shown of a method 800 for efficiently creating integrated circuit layout for standard cells that utilizes techniques to reduce voltage droop and reduce on-die area. For purposes of discussion, the steps in this implementation are shown in sequential order. However, in other implementations some steps occur in a different order than shown, some steps are performed concurrently, some steps are combined with other steps, and some steps are absent.

A semiconductor fabrication process forms, on a first node that receives a power supply reference, a first micro through silicon via (TSV) that traverses a silicon substrate layer to a backside metal layer (block 802). The semiconductor fabrication process (or process) places cells, such as standard cells, in an integrated circuit (block 804). The process also places power switches on the semiconductor die. The process routes a power supply signal from the output of the power switch to a frontside power rail using the micro TSV and the backside metal layer (block 806).

The process routes the power supply signal from the output of the power switch to the frontside power rail using a frontside metal layer (block 808). Therefore, the frontside metal layer and the backside metal layer provide power connection redundancy that increases charge sharing, improves wafer yield, reduces voltage droop, and reduces on-die area. In addition, the process routes a ground reference voltage level using both a frontside power rail and a backside power rail. If a potential is not applied to an input node of the integrated circuit (“no” branch of the conditional block 810), then the integrated circuit waits for power up (block 812). However, if a potential is applied to the input node of the integrated circuit (“yes” branch of the conditional block 810), then the integrated circuit conveys a current from the input node to an output node through the given cell (block 814).

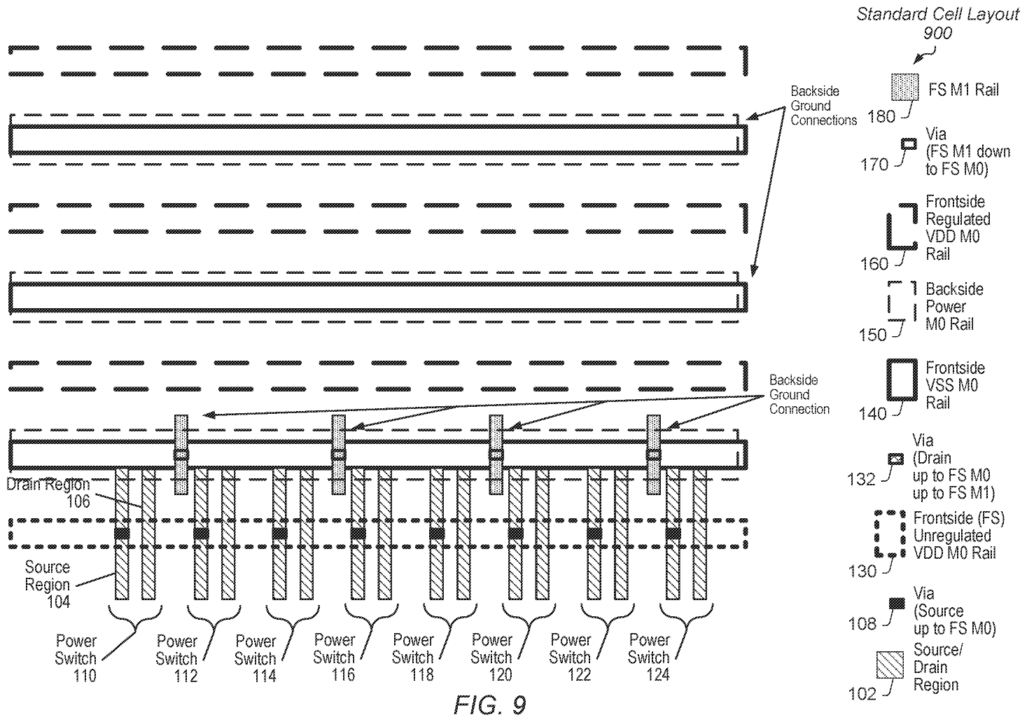

Turning now to FIG. 9, a generalized block diagram is shown of a top view of a standard cell layout 900 that utilizes techniques to reduce voltage droop and reduce on-ide area. The standard cell layout 900 includes the same contacts (or vias), materials, structures, and other layout elements as standard cell layout 100 (of FIG. 1). However, here, the backside power M0 rails 150 provide a ground voltage reference and are routed below the frontside VSS M0 rails 140 to provide an additional conductive routing layer. To transport current from an off-chip ground reference to n-type devices, the current flows from the off-chip ground reference to the frontside VSS M0 rail 140 at the bottom of layout 900, to the vias 170, to backside power M0 rails 150, and in some implementations, to backside power M1 rails.

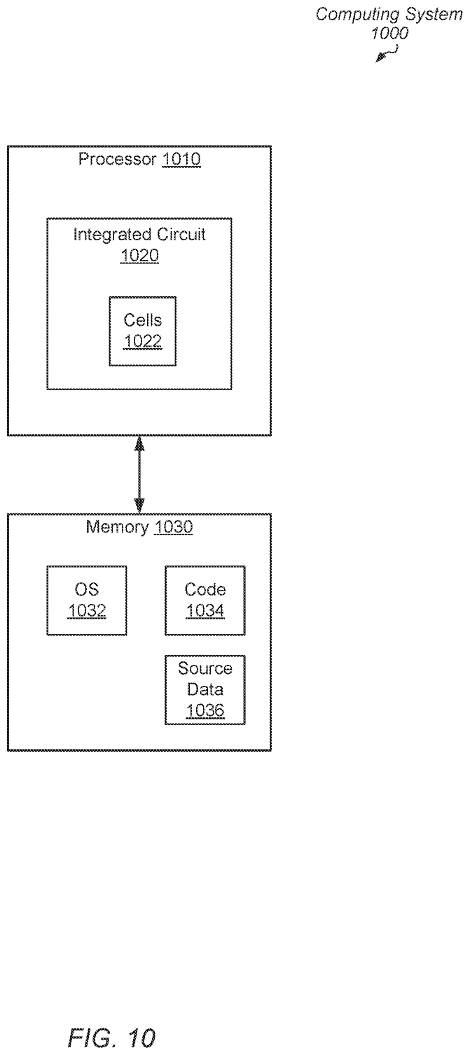

Referring to FIG. 10, a generalized block diagram is shown of a computing system 1000 with standard cells that utilizes techniques to reduce voltage droop and reduce on-die area. The computing system 1000 includes the processor 1010 and the memory 1030. Interfaces, such as a memory controller, a bus, or a communication fabric, one or more phased locked loops (PLLs) and other clock generation circuitry, a power management unit, and so forth, are not shown for ease of illustration. It is understood that in other implementations, the computing system 1000 includes one or more of other processors of a same type or a different type than processor 1010, one or more peripheral devices, a network interface, one or more other memory devices, and so forth. In some implementations, the functionality of the computing system 1000 is incorporated on a system on chip (SoC). In other implementations, the functionality of the computing system 1000 is incorporated on a peripheral card inserted in a motherboard. The computing system 1000 is used in any of a variety of computing devices such as a desktop computer, a tablet computer, a laptop, a smartphone, a smartwatch, a gaming console, a personal assistant device, and so forth.

The processor 1010 includes hardware such as circuitry. For example, the processor 1010 includes at least one integrated circuit 1020. The integrated circuit 1020 includes cells 1022 where one or more of these cells 1022 uses power connection redundancy that increases charge sharing, improves wafer yield, and reduces voltage droop. In various implementations, one or more of the cells 1022 uses power connection techniques used in the standard cell layouts 100 and 900 (of FIGS. 1 and 9), the power connections 200-500 (of FIGS. 2-5). In some implementations, the processor 1010 includes one or more processing units. In some implementations, each of the processing units includes one or more processor cores capable of general-purpose data processing, and an associated cache memory subsystem. In such an implementation, the processor 1010 is a central processing unit (CPU). In another implementation, the processing cores are compute units, each with a highly parallel data microarchitecture with multiple parallel execution lanes and an associated data storage buffer. In such an implementation, the processor 1010 is a graphics processing unit (GPU), a digital signal processor (DSP), or other.

In some implementations, the memory 1030 includes one or more of a hard disk drive, a solid-state disk, other types of flash memory, a portable solid-state drive, a tape drive and so on. The memory 1030 stores an operating system (OS) 1032, one or more applications represented by code 1034, and at least source data 1036. Memory 1030 is also capable of storing intermediate result data and final result data generated by the processor 1010 when executing a particular application of code 1034. Although a single operating system 1032 and a single instance of code 1034 and source data 1036 are shown, in other implementations, another number of these software components are stored in memory 1030. The operating system 1032 includes instructions for initiating the boot up of the processor 1010, assigning tasks to hardware circuitry, managing resources of the computing system 1000 and hosting one or more virtual environments.

Each of the processor 1010 and the memory 1030 includes an interface unit for communicating with one another as well as any other hardware components included in the computing system 1000. The interface units include queues for servicing memory requests and memory responses, and control circuitry for communicating with one another based on particular communication protocols. The communication protocols determine a variety of parameters such as supply voltage levels, power-performance states that determine an operating supply voltage and an operating clock frequency, a data rate, one or more burst modes, and so on.

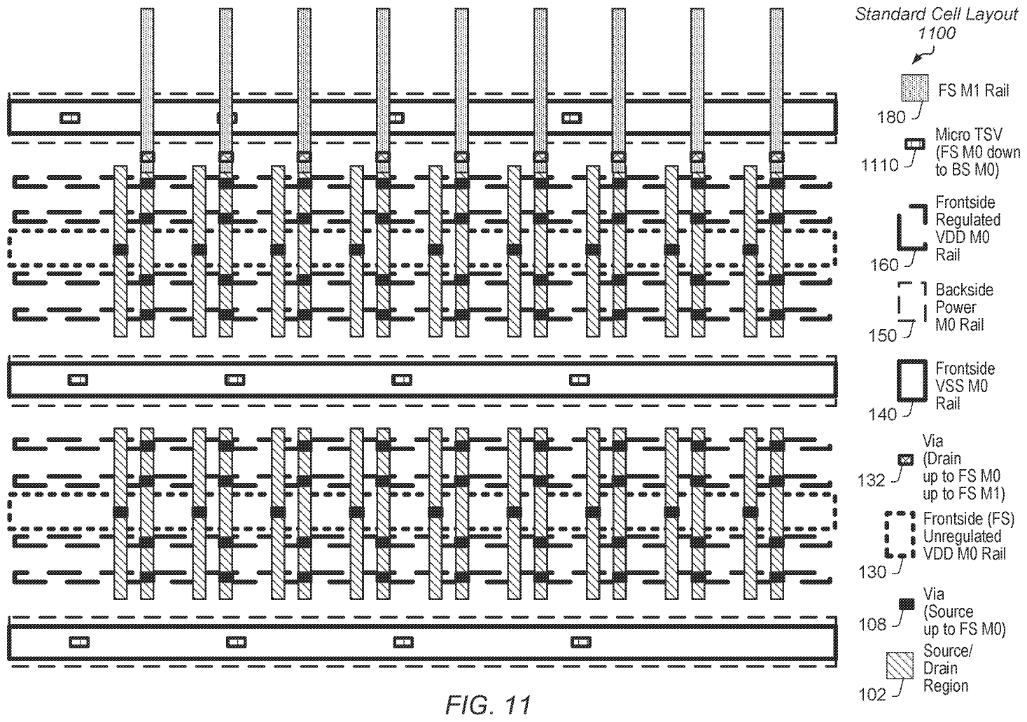

Turning now to FIG. 11, a generalized block diagram is shown of a top view of a standard cell layout 1100 that utilizes techniques to reduce voltage droop and reduce on-ide area. The standard cell layout 1100 includes the same contacts (or vias), materials, structures, and other layout elements as standard cell layouts 100, 600 and 900 (of FIGS. 1, 6 and 9). The backside power M0 rails 150 are routed below the frontside VSS M0 rails 140 to provide an additional conductive routing layer. A micro through silicon via (TSV) 1110 traverses the silicon substrate layer to reach the backside power M0 rails 150. The backside power M0 rails 150 are below the silicon substrate layer. Previously, the vias 170 and the frontside metal 1 (M1 or Metal1) rails 180 hid the micro TSVs 1110. To transport current from an off-chip ground reference to devices, the current flows from the off-chip ground reference to the frontside VSS M0 rail 140, to the micro TSVs 1110, to backside power M0 rails 150, and in some implementations, to backside power M1 rails.

In various implementations, the micro TSV 1110 has the same materials, functionality, and construction as the micro TSV 210 (of FIG. 2). The micro TSV 1110 traverses through the silicon substrate layer from the backside power M0 rail 150 to the frontside VSS M0 rails 140, and ends with physical contact at each of the backside power M0 rail 150 and the frontside VSS M0 rails 140. The distance between the backside power M0 rail 150 and the frontside VSS M0 rails 140 defines the height or length of the micro TSV 1110, which traverses only the silicon substrate layer and any oxide layer above the backside power M0 rail 150. The micro TSV 1110 does not physically extend into multiple insulation layers of a semiconductor die used for routing multiple frontside metal layers. Similarly, the micro TSV 1110 does not physically extend into multiple insulation layers of the semiconductor die used for routing multiple backside metal layers. Although the frontside VSS M0 rails 140 are routed over the micro TSVs 1110, the micro TSVs 1110 are shown here to further illustrate the use of power connection redundancy that improves wafer yield and reduces voltage droop.

Similar to the layout 100, 600 and 900 (of FIGS. 1, 6 and 9), the layout 1100 uses multiple power switches, which do not include callouts due to the lack of area in the figure. However, the implementation of these power switches is the same implementation as used in the layout 100, 600 and 900 (of FIGS. 1, 6 and 9). The source terminal (region) of a device is located to the left of the figure of a drain terminal (region). The source terminal receives the frontside unregulated VDD M0 rail 130 through the via 108. The drain terminal sends a gated (regulated) power supply reference voltage level to one or more of the frontside regulated VDD M0 rails 160 through the via 108. In addition, as shown at the top of FIG. 11, the drain terminal of some power switches is also connected to the frontside metal 1 (M1 or Metal1) rail 180 through the M0 layer (such as a stub) and the via 132. Although not shown, in some implementations, the drain terminals of some power switches located at the bottom of FIG. 11 are capable of being connected to frontside M1 rails 180 (not shown) located at the bottom of the layout 1100. It is noted again that the vias 132 and 170 and the backside power M0 rail 150 would not be visible from a top view of layout 1100 due to being covered by one or more of the M1 rail 180, other vias, the silicon substrate layer, the M0 layer (such as a stub or a signal route), and so forth. However, these components are shown here to illustrate particular power connections.

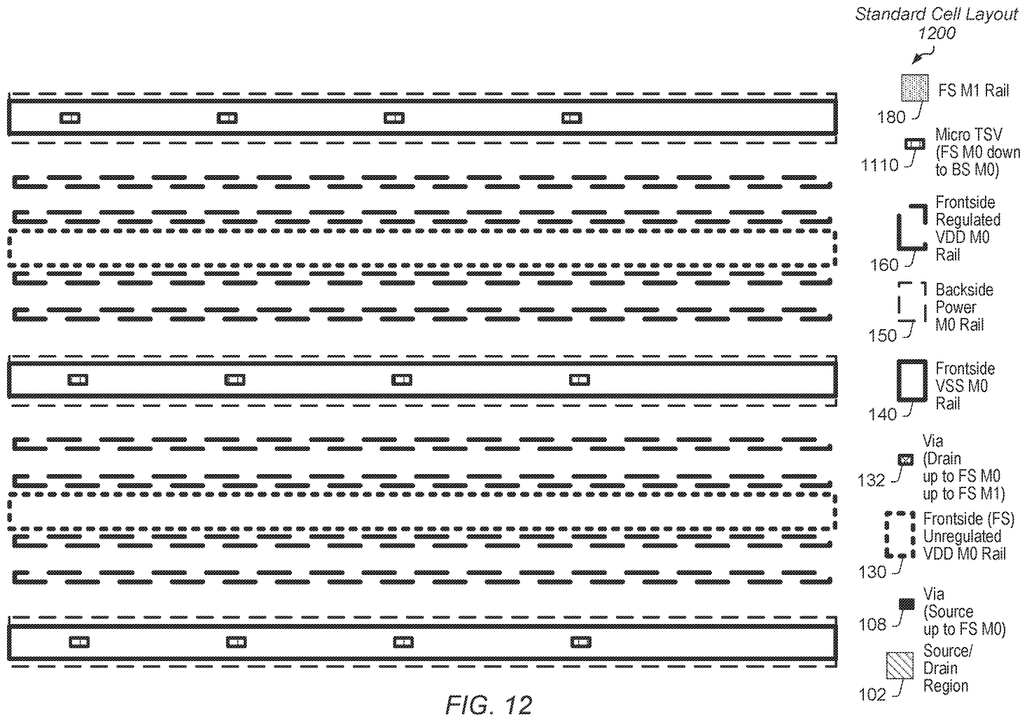

Turning to FIG. 12, a generalized block diagram is shown of a top view of a standard cell layout 1200 that utilizes techniques to reduce voltage droop and reduce on-ide area. The standard cell layout 1200 includes the same contacts (or vias), materials, structures, and other layout elements as standard cell layout 1100 (of FIG. 12). The layout 1200 has the power switches and corresponding vias removed to provide a clearer image of the power connections used in both the frontside M0 layer and the backside M0 layer.

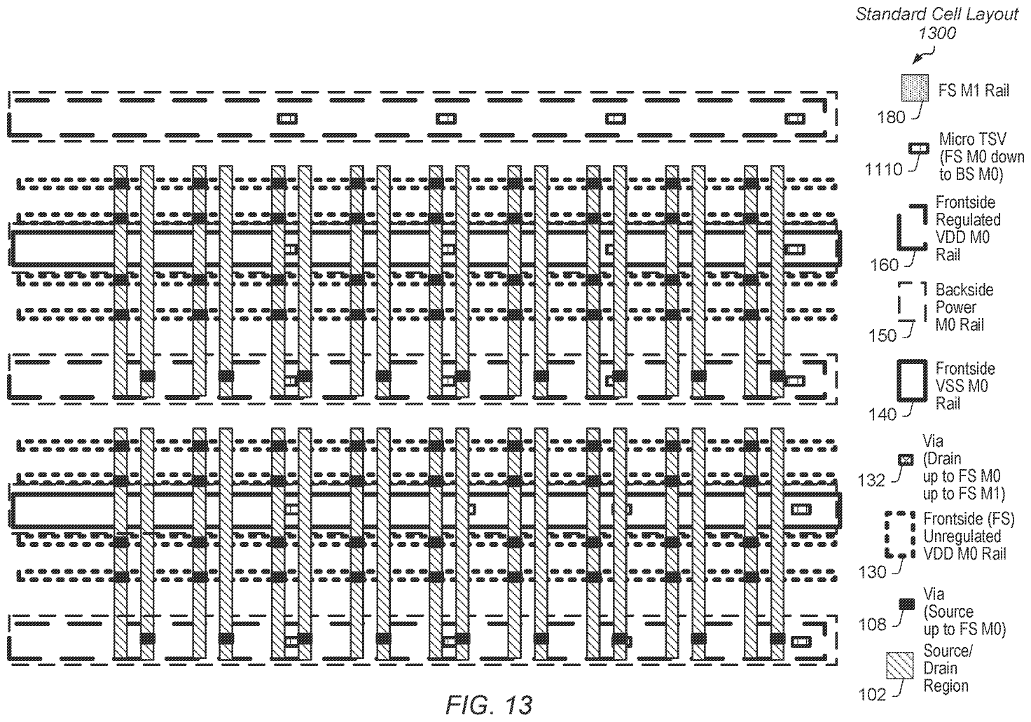

Referring to FIG. 13, a generalized block diagram is shown of a top view of a standard cell layout 1300 that utilizes techniques to reduce voltage droop and reduce on-ide area. The standard cell layout 1300 includes the same contacts (or vias), materials, structures, and other layout elements as standard cell layouts 100, 600, 900 and 1100-1200 (of FIGS. 1, 6, 9 and 11-12). The layout 1300 uses a same pattern of frontside M0 layers as layout 1100 such as using the same metal widths, metal pitches, and metal layer placements as layout 1100. However, the layout 1300 changes the assignment of the signals to these frontside M0 layers. The frontside M0 layers include the frontside unregulated VDD M0 rail 130, the frontside VSS M0 rail 140, and the frontside regulated VDD M0 rails 160. As shown, the layout 1100 has relatively thin width frontside regulated VDD M0 rails 160 on either side of a relatively wide width frontside unregulated VDD M0 rail 130. In contrast, the layout 1300 has relatively thin width frontside unregulated VDD M0 rails 130 on either side of a relatively wide width frontside VSS M0 rail 140.

In addition, the layout 1100 (and layout 1200) has relatively wide width frontside VSS M0 rails 140 between groupings of the relatively thin width frontside regulated VDD M0 rails 160 on either side of a relatively wide width frontside unregulated VDD M0 rail 130. The relatively wide width frontside VSS M0 rails 140 have power connections to the backside power M0 rails 150 via the micro TSVs 1110. In contrast, the layout 1300 has relatively thin width frontside unregulated VDD M0 rails 130 on either side of a relatively wide width frontside VSS M0 rail 140. The relatively wide width frontside regulated VDD M0 rails 160 have power connections to the backside power M0 rails 150 via the micro TSVs 1110.

Further, the relatively wide width frontside VSS M0 rails 140 of layout 1300 also have power connections to the backside power M0 rails 150 via the micro TSVs 1110. Therefore, by switching the assignments of the signals in layout 1300 while using the same pitch, widths, and placements of frontside M0 layers found in the layout 1100 (and layout 1200), the layout 1300 includes more power connections to the backside power M0 rails 150 via the micro TSVs 1110 than found in layout 1100. Further still, the layout 1300 does not require using frontside M1 rails 180 to connect frontside unregulated VDD M0 rails 130 to frontside regulated VDD M0 rails 160. The absence of frontside M1 rails 180 for this type of connection allows the standard cells to use the available frontside M1 tracks.

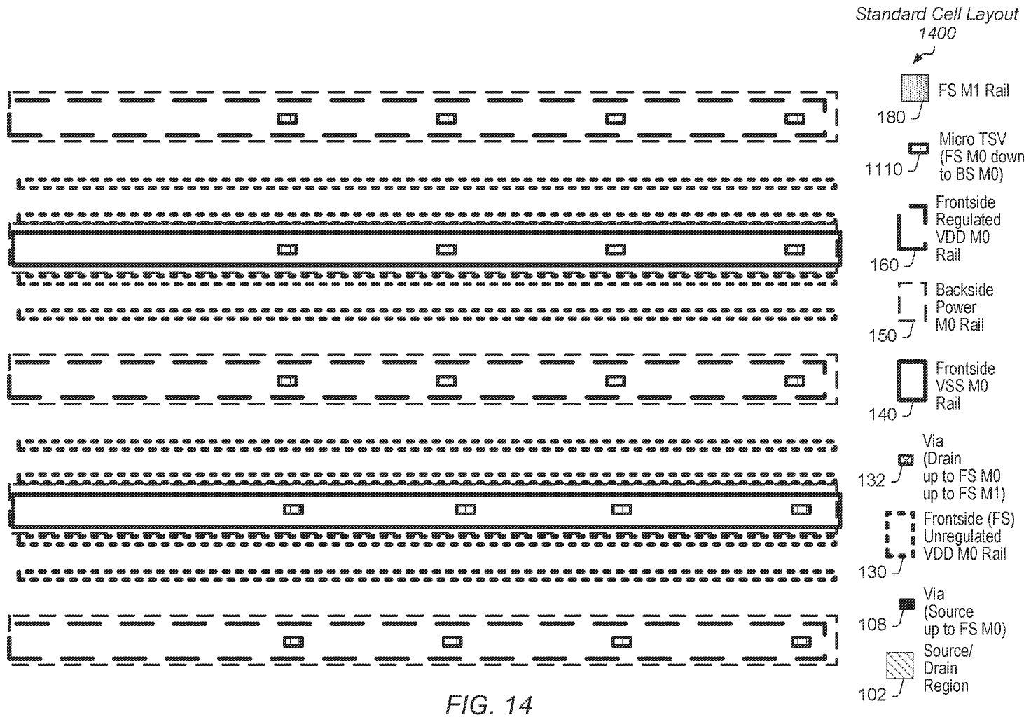

Turning to FIG. 14, a generalized block diagram is shown of a top view of a standard cell layout 1400 that utilizes techniques to reduce voltage droop and reduce on-ide area. The standard cell layout 1400 includes the same contacts (or vias), materials, structures, and other layout elements as standard cell layout 1300 (of FIG. 13). The layout 1400 has the power switches and corresponding vias removed to provide a clearer image of the power connections used in both the frontside M0 layer and the backside M0 layer.

It is noted that one or more of the above-described implementations include software. In such implementations, the program instructions that implement the methods and/or mechanisms are conveyed or stored on a computer readable medium. Numerous types of media which are configured to store program instructions are available and include hard disks, floppy disks, CD-ROM, DVD, flash memory, Programmable ROMs (PROM), random access memory (RAM), and various other forms of volatile or non-volatile storage. Generally speaking, a computer accessible storage medium includes any storage media accessible by a computer during use to provide instructions and/or data to the computer. For example, a computer accessible storage medium includes storage media such as magnetic or optical media, e.g., disk (fixed or removable), tape, CD-ROM, or DVD-ROM, CD-R, CD-RW, DVD-R, DVD-RW, or Blu-Ray. Storage media further includes volatile or non-volatile memory media such as RAM (e.g., synchronous dynamic RAM (SDRAM), double data rate (DDR, DDR2, DDR3, etc.) SDRAM, low-power DDR (LPDDR2, etc.) SDRAM, Rambus DRAM (RDRAM), static RAM (SRAM), etc.), ROM, Flash memory, non-volatile memory (e.g., Flash memory) accessible via a peripheral interface such as the Universal Serial Bus (USB) interface, etc. Storage media includes microelectromechanical systems (MEMS), as well as storage media accessible via a communication medium such as a network and/or a wireless link.

Additionally, in various implementations, program instructions include behavioral-level descriptions or register-transfer level (RTL) descriptions of the hardware functionality in a high level programming language such as C, or a design language (HDL) such as Verilog, VHDL, or database format such as GDS II stream format (GDSII). In some cases, the description is read by a synthesis tool, which synthesizes the description to produce a netlist including a list of gates from a synthesis library. The netlist includes a set of gates, which also represent the functionality of the hardware including the system. The netlist is then placed and routed to produce a data set describing geometric shapes to be applied to masks. The masks are then used in various semiconductor fabrication steps to produce a semiconductor circuit or circuits corresponding to the system. Alternatively, the instructions on the computer accessible storage medium are the netlist (with or without the synthesis library) or the data set, as desired. Additionally, the instructions are utilized for purposes of emulation by a hardware based type emulator from such vendors as Cadence®, EVE®, and Mentor Graphics®.

Although the implementations above have been described in considerable detail, numerous variations and modifications will become apparent to those skilled in the art once the above disclosure is fully appreciated. It is intended that the following claims be interpreted to embrace all such variations and modifications.

What is claimed is:

1. An integrated circuit comprising:
a first power rail of a plurality of frontside metal layers with a voltage equal to an off-chip power supply reference received through the plurality of frontside metal layers; and
a backside metal layer, connected to each of the first power rail and the second power rail, configured to route the power supply reference from the first power rail to a second power rail different from the first power rail; and
wherein responsive to a potential being applied to an input node of a cell of the integrated circuit, a current is conveyed from the input node to an output node of the cell through one of the first power rail and the second power rail.

2. The integrated circuit as recited in claim 1, further comprising a micro through silicon via (TSV) that traverses through a silicon substrate layer between the first power rail and the backside metal layer.

3. The integrated circuit as recited in claim 2, further comprising a power switch between the first power rail and a third power rail connected to the off-chip power supply reference through the plurality of frontside metal layers, wherein the power switch is configured to:
connect the third power rail to the micro TSV, responsive to the power switch being enabled; and
disconnect the first power rail from the micro TSV, responsive to the power switch being disabled.

4. The integrated circuit as recited in claim 3, further comprising a first frontside metal layer of the plurality of frontside metal layers connected to each of an output of the power switch and the first power rail configured to route the power supply reference from the third power rail to the first power rail.

5. The integrated circuit as recited in claim 4, wherein the first frontside metal layer is further connected to the second power rail and routes the power supply reference from the first power rail to the second power rail.

6. The integrated circuit as recited in claim 4, wherein one or more of a thickness and a width of the backside metal layer is greater than a thickness and a width of the first frontside metal layer.

7. The integrated circuit as recited in claim 4, wherein:
each of the first power rail and the second power rail is a metal layer of the plurality of frontside metal layers located closest to active devices of the integrated circuit; and
the first frontside metal layer is a metal layer adjacent to the first power rail.

8. A method comprising:
growing a silicon substrate layer of an integrated circuit;
forming, in the integrated circuit along a first surface of the silicon substrate layer, a plurality of transistors;
forming a first power rail of a plurality of frontside metal layers with a voltage equal to an off-chip power supply reference received through the plurality of frontside metal layers; and
forming a backside metal layer connected to each of the first power rail and the second power rail configured to route the power supply reference from the first power rail to the second power rail different from the first power rail; and
responsive to a power supply voltage being applied to an input node of a cell of the integrated circuit, conveying a current from the input node to an output node of the cell through one of the first power rail and the second power rail.

9. The method as recited in claim 8, further comprising forming a micro through silicon via (TSV) that traverses through a silicon substrate layer between the first power rail and the backside metal layer.

10. The method as recited in claim 9, further comprising forming a power switch between the first power rail and a third power rail connected to the off-chip power supply reference through the plurality of frontside metal layers, wherein the method further comprises:
connecting, by the power switch, the third power rail to the micro TSV, responsive to the power switch being enabled; and
disconnecting, by the power switch, the first power rail from the micro TSV, responsive to the power switch being disabled.

11. The method as recited in claim 10, further comprising forming a first frontside metal layer of the plurality of frontside metal layers connected to each of an output of the power switch and the first power rail, wherein the method further comprises routing, by the first frontside metal layer, the power supply reference from the third power rail to the first power rail.

12. The method as recited in claim 11, further comprising routing the power supply reference from the first power rail to the second power rail by the first frontside metal layer connected to the second power rail.

13. The method as recited in claim 11, wherein one or more of a thickness and a width of the backside metal layer is greater than a thickness and a width of the first frontside metal layer.

14. The method as recited in claim 11, wherein:
each of the first power rail and the second power rail is a metal layer of the plurality of frontside metal layers located closest to active devices of the integrated circuit; and
the first frontside metal layer is a metal layer adjacent to the first power rail.

15. A computing system comprising:
a memory configured to store instructions of one or more tasks and source data to be processed by the one or more tasks;
an integrated circuit configured to execute the instructions using the source data, wherein the integrated circuit comprises:
a first power rail of a plurality of frontside metal layers with a voltage equal to an off-chip power supply reference received through the plurality of frontside metal layers; and
a backside metal layer connected to each of the first power rail and the second power rail configured to route the power supply reference from the first power rail to a second power rail different from the first power rail; and
wherein responsive to a potential being applied to an input node of a cell of the integrated circuit, a current is conveyed from the input node to an output node of the cell through one of the first power rail and the second power rail.

16. The computing system as recited in claim 15, wherein the integrated circuit further comprises a micro through silicon via (TSV) that traverses through a silicon substrate layer between the first power rail and the backside metal layer.

17. The computing system as recited in claim 16, wherein the integrated circuit further comprises a power switch between the first power rail and a third power rail connected to the off-chip power supply reference through the plurality of frontside metal layers, wherein the power switch is configured to:
connect the third power rail to the micro TSV, responsive to the power switch being enabled; and
disconnect the first power rail from the micro TSV, responsive to the power switch being disabled.

18. The computing system as recited in claim 17, wherein the integrated circuit further comprises a first frontside metal layer of the plurality of frontside metal layers connected to each of an output of the power switch and the first power rail configured to route the power supply reference from the third power rail to the first power rail.

19. The computing system as recited in claim 18, wherein the first frontside metal layer is further connected to the second power rail and routes the power supply reference from the first power rail to the second power rail.

20. The computing system as recited in claim 18, wherein one or more of a thickness and a width of the backside metal layer is greater than a thickness and a width of the first frontside metal layer.
